(19) United States
(12) Patent Application Publication
(10) Pub. No.: US 2020/0232088 A1
(43) Pub. Date: Jul. 23, 2020

(54) APPARATUS AND SYSTEM FOR VACUUM DEPOSITION ON A SUBSTRATE AND METHOD FOR VACUUM DEPOSITION ON A SUBSTRATE

(71) Applicant: Applied Materials, Inc., Santa Clara, US (US)

(72) Inventors: John M. WHITE, Hayward, CA (US); Oliver GRAW, Alzenau (DE)

(73) Assignees: Applied Materials, Inc., Santa Clara, CA (US); Applied Materials, Inc., Santa Clara, CA (US)

(21) Appl. No.: 15/758,837

(22) PCT Filed: Apr. 28, 2016
(86) PCT No.: PCT/EP2016/059532

§ 371 Date: Mar. 9, 2018

Related U.S. Application Data
(60) Provisional application No. 62/246,095, filed on Oct. 25, 2015.
(60) Provisional application No. 62/246,401, filed on Oct. 26, 2015.
(60) Provisional application No. 62/252,900, filed on Nov. 9, 2015.

(51) Int. Cl. C23C 14/35; C23C 14/24; C23C 14/34; C23C 14/56; C23C 16/54; C23C 14/50; H01J 37/34; H01J 37/32

(52) U.S. Cl. CPC C23C 14/35; C23C 14/24; C23C 14/3407; C23C 14/566; C23C 14/568; H01J 2237/20278; C23C 14/50; H01J 37/3405; H01J 37/32724; H01J 2237/3321; H01J 37/3452; C23C 16/54

(57) ABSTRACT

The present disclosure provides an apparatus for vacuum deposition on a substrate. The apparatus includes a vacuum chamber having a first area and a first deposition area, one or more deposition sources at the first deposition area, wherein the one or more deposition sources are configured for vacuum deposition on at least a first substrate while the at least a first substrate is transported along a first transport direction past the one or more deposition sources, and a first substrate transport unit in the first area, wherein the first substrate transport unit is configured for moving the at least a first substrate within the first area in a first track switch direction, which is different from the first transport direction.

### FIELD

Embodiments of the present disclosure relate to an apparatus for vacuum deposition on a substrate, a system configured for vacuum deposition on a substrate, and a method for vacuum deposition on a substrate. Embodiments of the present disclosure particularly relate to a dual-line sputter deposition apparatus, and more particularly to a dynamic dual-line sputter deposition apparatus.

### BACKGROUND

Techniques for layer deposition on a substrate include, for example, sputter deposition, thermal evaporation, and chemical vapor deposition. A sputter deposition process can be used to deposit a material layer on the substrate, such as a layer of a conducting material or an insulating material. During the sputter deposition process, a target having a target material to be deposited on the substrate is bombarded with ions generated in a plasma region to dislodge atoms of the target material from a surface of the target. The dislodged atoms can form the material layer on the substrate. In a reactive sputter deposition process, the dislodged atoms can react with a gas in the plasma region, for example, nitrogen or oxygen, to form an oxide, a nitride or an oxynitride of the target material on the substrate.

Coated materials may be used in several applications and in several technical fields. For instance, an application lies in the field of microelectronics, such as generating semiconductor devices. Also, substrates for displays are often coated by a sputter deposition process. Further applications include insulating panels, substrates with TFT, color filters or the like.

As an example, in display manufacturing, it is beneficial to reduce manufacturing costs of displays, e.g., for mobile phones, tablet computers, television screens, and the like. A reduction in manufacturing costs can be achieved, for example, by increasing a throughput of a processing apparatus, such as a sputter deposition apparatus.

In view of the above, apparatuses, systems and methods for vacuum deposition on a substrate that overcome at least some of the problems in the art are beneficial. The present disclosure particularly aims at providing apparatuses and methods that provide for an increased throughput.

### SUMMARY

In light of the above, an apparatus for vacuum deposition on a substrate, a system configured for vacuum deposition on a substrate, and a method for vacuum deposition on a substrate are provided. Further aspects, benefits, and features of the present disclosure are apparent from the claims, the description, and the accompanying drawings.

According to an aspect of the present disclosure, an apparatus for vacuum deposition on a substrate is provided. The apparatus includes a vacuum chamber having a first area and a first deposition area, one or more deposition sources at the first deposition area, wherein the one or more deposition sources are configured for vacuum deposition on at least a first substrate while the at least a first substrate is transported along a first transport direction past the one or more deposition sources, and a first substrate transport unit in the first area, wherein the first substrate transport unit is configured for moving the at least a first substrate within the first area in a first track switch direction, which is different from the first transport direction.

According to another aspect of the present disclosure, a system configured for vacuum deposition on a substrate is provided. The system includes the apparatus according to the embodiments described herein, and a load lock chamber connected to the apparatus, wherein the load lock chamber is configured to load substrates into the first area and to receive substrates from the first area.

According to yet another aspect of the present disclosure, a method for vacuum deposition on a substrate is provided. The method includes moving at least a first substrate in a first transport direction along a first transportation path through a first deposition area of a vacuum chamber past one or more deposition sources to deposit a material layer on the at least a first substrate, and moving the at least a first substrate in a first track switch direction different from the first transport direction at least one of before and after the material layer has been deposited on the at least a first substrate.

According to a further aspect of the present disclosure, an apparatus for vacuum deposition on a substrate is provided. The apparatus includes a vacuum chamber having at least a first area and a deposition area, and one or more deposition sources at the deposition area and configured for vacuum deposition on the substrate while the substrate is transported along a transport direction past the one or more deposition sources. The first area extends sufficiently along the transport direction to allow for a movement of the substrate substantially transverse to the transport direction within the first area.

According to a yet further aspect of the present disclosure, a method for vacuum deposition on a substrate is provided. The method includes a moving of the substrate along a transport direction through a deposition area of a vacuum chamber past one or more deposition sources to deposit a material layer on the substrate, and a moving of the substrate substantially transverse to the transport direction within a first area of the vacuum chamber at least one of before and after the deposition of the material layer on the substrate.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic top view of an apparatus for vacuum deposition on a substrate according to embodiments described herein;

FIG. 1B shows a schematic top view of an apparatus for vacuum deposition on a substrate according to further embodiments described herein;

FIG. 2 shows a schematic top view of an apparatus for vacuum deposition on a substrate according to embodiments described herein;

FIG. 3 shows a schematic top view of an apparatus for vacuum deposition on a substrate according to yet further embodiments described herein;

FIG. 4 shows schematic views of loop-shaped transportation paths in the vacuum chamber according to embodiments described herein;

FIG. 5 shows a schematic top view of a bi-directional sputter deposition source used for a simultaneous processing of two or more substrates according to embodiments described herein;

FIG. 6 shows a schematic view of a lateral displacement of the carrier having the substrate positioned thereon according to embodiments described herein; and

FIG. 7 shows a flow chart of a method for vacuum deposition on a substrate according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The present disclosure provides an apparatus (also referred to as “processing module”) for vacuum deposition including multiple transport possibilities for substrates within a vacuum chamber in a plurality of different directions. In particular, multiple transportation paths extending through a plurality of distinct areas within a vacuum chamber are provided such that a plurality of substrates can be processed simultaneously.

As an example, the vacuum chamber can have at least two distinct areas, such as a deposition area and at least one of a first area, a second area, and a transportation area. The areas are distinct from each other and do not overlap. The first area and optionally the second area can provide an additional degree of freedom for the substrate movement. The additional degree of freedom, which is a movement of the substrate in a track switch direction, e.g., substantially transverse to the transport direction past the deposition sources, allows for an increased number of substrates that can be simultaneously put and/or processed in the vacuum chamber. In particular, an increased number of substrates can be handled simultaneously within the vacuum chamber. An efficiency and throughput of the apparatus for vacuum deposition can be increased. The transportation area, which can be shielded from the deposition sources using, for example, substrates transported through the deposition area or a partition, can extend substantially parallel to the deposition area and can provide a return path for coated substrates. In particular, coated substrates can be returned to an original position and can, for example, exit the vacuum chamber through the same load lock through which the uncoated substrate has entered the vacuum chamber.

In some implementations, the vacuum chamber can be configured to provide a loop-shaped transportation path for the substrates within the vacuum chamber, for example, using the first area and the second area with the deposition area being sandwiched between the first area and the second area. An efficiency and throughput of the apparatus can be further increased. The vacuum chamber can have a reduced number of load locks, such as gate valves, used for inserting the substrate into, and removing the substrate from, the vacuum chamber. A complexity of the apparatus for vacuum deposition can be reduced.

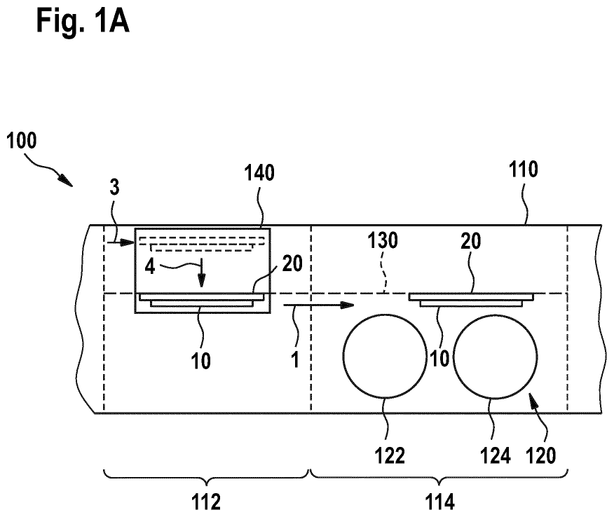

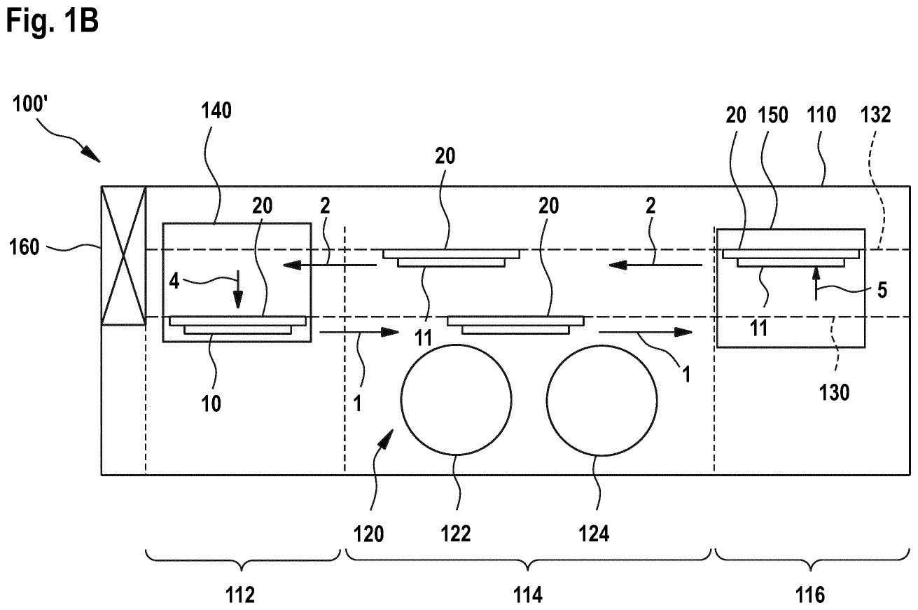

FIG. 1A shows a section of an apparatus 100 for vacuum deposition on a substrate according to embodiments described herein.

According to some embodiments, which can be combined with other embodiments described herein, the apparatus 100 includes a vacuum chamber 110 having a first area 112 and a deposition area, such as a first deposition area 114, and one or more deposition sources 120 at or in the deposition area. One or more further areas such as a second area can be provided in the vacuum chamber 110, for example, adjacent to the first deposition area 114. The one or more deposition sources 120 are configured for vacuum deposition, such as sputter deposition, on at least a first substrate 10 in the first deposition area 114 while the at least a first substrate 10 is transported along a transport direction, such as a first transport direction 1, past the one or more deposition sources 120. The apparatus 100 is configured for substrate transportation in the first transport direction 1 along a first transportation path 130 through the first deposition area 114. As an example, the first transportation path 130 extends through the first area 112 and the first deposition area 114.

According to some embodiments, which can be combined with other embodiments described herein, the one or more deposition sources 120 can be sputter deposition sources, e.g., bi-directional sputter deposition sources. However, the present disclosure is not limited to sputter deposition sources, and other deposition sources for conducting physical vapor deposition (PVD) and/or chemical vapor deposition (CVD) processes can be provided. As an example, the one or more deposition sources 120 can be selected from the group consisting of sputter deposition sources, thermal evaporation sources, plasma-enhanced chemical vapor deposition sources, and any combination thereof.

The apparatus 100 includes a first substrate transport unit 140 in the first area 112. The first substrate transport unit 140 is configured for moving the at least a first substrate 10 or carrier 20 having the at least a first substrate 10 positioned thereon within the first area 112 in a first track switch direction 4, which is different from the first transport direction 1. As an example, the first substrate transport unit 140 can be configured to move the at least a first substrate 10 or carrier 20 onto the first transportation path 130 and/or to remove the at least a first substrate 10 or carrier 20 from the first transportation path 130.

The first area 112 extends sufficiently along the first transport direction 1 to allow for a movement of the at least a first substrate 10 in the first track switch direction 4. The first track switch direction 4 can be substantially transverse or perpendicular to the first transport direction 1 within the first area 112. As an example, the first substrate transport unit 140 can be configured to laterally displace the at least a first substrate 10. The term “substantially transverse” is understood particularly when referring to the movement of the substrate e.g. in the first area 112 in the first track switch direction 4 to allow for a deviation from the exact transverse or perpendicular movement of ±20° or below, e.g. of ±10° or below. Yet, the movement of the substrate in the track switch direction is considered substantially transverse.

In some implementations, an extension of the first area 112 along the transport direction, such as the first transport direction 1, can be equal to, or greater than, a width of the at least a first substrate 10 or the carrier 20 on which the at least a first substrate 10 is positioned. The width can correspond to a distance between a leading edge and a trailing edge of the substrate or the carrier 20 parallel to the first transport direction 1. As an example, the extension of the first area 112 along the first transport direction 1 can be sufficient to allow for a substantially transverse movement of large area substrates. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The at least a first substrate 10 can be inserted into the first area 112 of the vacuum chamber 110, e.g., through a load lock (not shown), as indicated with arrow 3. The at least a first substrate 10 can then be moved in the first track switch direction 4, e.g., transverse to the first transport direction 1, and onto a transportation path, such as the first transportation path 130. The first transportation path 130 extends along the first transport direction 1 past the one or more deposition sources 120. In some implementations, another substrate can be inserted into the first area 112 while the at least a first substrate 10 is still positioned on the first transportation path 130 in the first area 112. Accordingly, an increased number of substrates can be simultaneously provided in the vacuum chamber 110.

According to some embodiments, which can be combined with other embodiments described herein, the first substrate transport unit 140 is configured to laterally displace the at least a first substrate 10 in the first track switch direction 4. In some implementations, the first substrate transport unit 140 can be a lateral displacement mechanism.

The at least a first substrate 10 that has been moved in the first track switch direction 4 onto the first transportation path 130 is transported along the first transport direction 1 past the one or more deposition sources 120, such as one or more bi-directional deposition sources. While the at least a first substrate 10 is moved past the one or more deposition sources 120, a vacuum deposition process, such as a sputter deposition process, is performed in order to deposit a material layer on the at least a first substrate 10.

The one or more deposition sources 120 can include at least a first deposition source 122, such as a first sputter deposition source, and a second deposition source 124, such as a second sputter deposition source. However, the present disclosure is not limited thereto, and any suitable number of deposition sources can be provided, for example, one deposition source or more than two deposition sources. In some implementations, the one or more deposition sources 120 can be sputter deposition sources connected to an AC power supply (not shown) such that the one or more deposition sources 120 can be powered, e.g., in an alternating paired manner. However, the present disclosure is not limited thereto and the one or more deposition sources 120 can be configured for DC sputtering or a combination of AC and DC sputtering.

According to some embodiments, one single vacuum chamber, such as the vacuum chamber 110, for deposition of layers therein can be provided. A configuration with one single vacuum chamber having a plurality of areas, such as the first area 112 and the first deposition area 114, can be beneficial in an in-line processing apparatus, for example, for dynamic deposition. The one single vacuum chamber with different areas does not include devices for vacuum tight sealing of one area (e.g., the first area 112) of the vacuum chamber 110 with respect to another area (e.g., the first deposition area 114) of the vacuum chamber 110.

In some implementations, further chambers can be provided adjacent to the vacuum chamber 110, such as load lock chambers and/or further processing chambers. The vacuum chamber 110 can be separated from adjacent chambers by a valve, which may have a valve housing and a valve unit. As an example, a system configured for vacuum deposition on a substrate may include the apparatus according to the embodiments described herein, and a load lock chamber connected to the apparatus, wherein the load lock chamber is configured to load substrates into the first area 112 and to receive substrates from the first area 112.

In some embodiments, an atmosphere in the vacuum chamber 110 can be individually controlled by generating a technical vacuum, for example with vacuum pumps connected to the vacuum chamber 110, and/or by inserting process gases in the deposition area(s) in the vacuum chamber 110. According to some embodiments, process gases can include inert gases such as argon and/or reactive gases such as oxygen, nitrogen, hydrogen and ammonia (NH3), Ozone (O3), or the like.

In some implementations, the apparatus 100 includes one or more transportation paths, such as the first transportation path 130, at least partially extending through the vacuum chamber 110. As an example, the first transportation path 130 can start in and/or extend through the first area 112 and can further extend through the deposition area, such as the first deposition area 114. The one or more transportation paths can provide, or be defined by, a transport direction past the one or more deposition sources 120, such as the first transport direction 1. Although the example of FIG. 1A shows a unidirectional transport direction, the present disclosure is not limited thereto and the transport direction can be bi-directional. In other words, according to some embodiments, the substrate can be transported in a first direction and a second direction opposite the first direction on the same transportation path.

The substrates can be positioned on respective carriers. The carriers 20 can be configured for transportation along the one or more transportation paths or transportation tracks extending in one or more transport directions, such as the first transport direction 1. Each carrier 20 is configured to support the substrate, for example, during a vacuum deposition process or layer deposition process, such as a sputtering process or a dynamic sputtering process. The carrier 20 can include a plate or a frame configured for supporting the substrate, for example, using a support surface provided by the plate or frame. Optionally, the carrier 20 can include one or more holding devices (not shown) configured for holding the substrate at the plate or frame. The one or more holding devices can include at least one of mechanical, electrostatic, electrodynamic (van der Waals), and electromagnetic devices. As an example, the one or more holding devices can be mechanical and/or magnetic clamps.

In some implementations, the carrier 20 includes, or is, an electrostatic chuck (E-chuck). The E-chuck can have a supporting surface for supporting the substrate thereon. In one embodiment, the E-chuck includes a dielectric body having electrodes embedded therein. The dielectric body can be fabricated from a dielectric material, preferably a high thermal conductivity dielectric material such as pyrolytic boron nitride, aluminum nitride, silicon nitride, alumina or an equivalent material. The electrodes may be coupled to a power source, which provides power to the electrodes to control a chucking force. The chucking force is an electrostatic force acting on the substrate to fix the substrate on the supporting surface.

In some implementations, the carrier 20 includes, or is, an electrodynamic chuck or Gecko chuck (G-chuck). The G-chuck can have a supporting surface for supporting the substrate thereon. The chucking force is an electrodynamic force acting on the substrate to fix the substrate on the supporting surface.

According to some embodiments, which can be combined with other embodiments described herein, the substrate, such as the at least a first substrate 10, is in a substantially vertical orientation, for example, during the vacuum deposition process and/or during transportation of the substrate through the vacuum chamber 110. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support or carrier with some deviation from the vertical orientation might result in a more stable substrate position or a facing down substrate orientation might even better reduce particles on the substrate during deposition. Yet, the substrate orientation, e.g., during a layer deposition process is considered substantially vertical, which is considered different from the horizontal substrate orientation, which may be considered as horizontal ±20° or below.

Specifically, as used throughout the present disclosure, terms such as “vertical direction” or “vertical orientation” are understood to distinguish over “horizontal direction” or “horizontal orientation”. The vertical direction can be substantially parallel to the force of gravity.

According to some embodiments, which can be combined with other embodiments described herein, the apparatus 100 is configured for dynamic sputter deposition on the substrate(s). A dynamic sputter deposition process can be understood as a sputter deposition process in which the substrate is moved through the deposition area along the transport direction while the sputter deposition process is conducted. In other words, the substrate is not stationary during the sputter deposition process.

In some implementations, the apparatus according to the embodiments described herein is configured for dynamic processing. The apparatus can particularly be an in-line processing apparatus, i.e. an apparatus for dynamic deposition, particularly for dynamic vertical deposition, such as sputtering. An in-line processing apparatus or a dynamic deposition apparatus according to embodiments described herein provides for a uniform processing of the substrate, for example, a large area substrate such as a rectangular glass plate. The processing tools, such as the one or more deposition sources 120, extend mainly in one direction (e.g., the vertical direction) and the substrate is moved in a second, different direction (e.g., the first transport direction 1, which can be a horizontal direction).

Apparatuses or systems for dynamic vacuum deposition, such as in-line processing apparatuses or systems, have the advantage that processing uniformity, for example, layer uniformity, in one direction is limited by the ability to move the substrate at a constant speed and to keep the one or more deposition sources stable. The deposition process of an in-line processing apparatus or a dynamic deposition apparatus is determined by the movement of the substrate past the one or more deposition sources. For an in-line processing apparatus, the deposition area or processing area can be an essentially linear area for processing, for example, a large area rectangular substrate. The deposition area can be an area into which deposition material is ejected from the one or more deposition sources for being deposited on the substrate. In contrast thereto, for a stationary processing apparatus, the deposition area or processing area would basically correspond to the area of the substrate.

In some implementations, a further difference of an in-line processing apparatus, for example, for dynamic deposition, as compared to a stationary processing apparatus can be formulated by the fact that the apparatus can have one single vacuum chamber with different areas, wherein the vacuum chamber does not include devices for vacuum tight sealing of one area of the vacuum chamber with respect to another area of the vacuum chamber. Contrary thereto, a stationary processing system may have a first vacuum chamber and a second vacuum chamber which can be vacuum tight sealed with respect to each other using, for example, valves.

According to some embodiments, which can be combined with other embodiments described herein, the apparatus 100 includes a magnetic levitation system for holding the carrier 20 in a suspended state. Optionally, the apparatus 100 can use a magnetic drive system configured for moving or conveying the carrier 20 in the transport direction, such as the first transport direction 1. The magnetic drive system can be included in the magnetic levitation system or can be provided as a separate entity.

The embodiments described herein can be utilized for vacuum deposition on large area substrates, e.g., for display manufacturing. Specifically, the substrates or carriers, for which the structures and methods according to embodiments described herein are provided, are large area substrates. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The term “substrate” as used herein shall particularly embrace inflexible substrates, e.g., glass plates and metal plates. However, the present disclosure is not limited thereto and the term “substrate” can also embrace flexible substrates such as a web or a foil. According to some embodiments, the substrate can be made of any material suitable for material deposition. For instance, the substrate can be made of a material selected from the group consisting of glass (for instance soda-lime glass, borosilicate glass, and the like), metal, polymer, ceramic, compound materials, carbon fiber materials, mica or any other material or combination of materials which can be coated by a deposition process.

FIG. 1B shows an apparatus 100′ for vacuum deposition on a substrate, such as the at least a first substrate 10, according to further embodiments described herein. The apparatus 100′ can be similar to the apparatus of FIG. 1A and thus, the description given with respect to FIG. 1A also applies to the apparatus 100′ of FIG. 1B.

According to some embodiments, which can be combined with other embodiments described herein, the apparatus 100′ includes at least a second area 116. The deposition area, such as the first deposition area 114, can be arranged between the first area 112 and the second area 116. Particularly, the deposition area, such as the first deposition area 114, can be sandwiched between the first area 112 and the second area 116.

In some implementations, the apparatus 100′ includes two or more transportation paths, such as the first transportation path 130 and a second transportation path 132, at least partially extending through the vacuum chamber 110. The two or more transportation paths can extend substantially parallel to each other. As an example, the first transportation path 130 can extend along the first transport direction 1 and the second transportation path 132 can extend along a third transport direction 2.

The second area 116 can be configured similarly or identically to the first area 112. As an example, the apparatus 100′ further includes a second substrate transport unit 150 in the second area 116. The second substrate transport unit 150 is configured for moving the at least a first substrate 10 within the second area 116 in a second track switch direction 5, which is different from the first transport direction 1 and/or the third transport direction 2. In particular, the second area 116 extends sufficiently along the transport direction, such as the first transport direction 1, to allow for a movement of the at least a first substrate 10 within the second area 116 in the second track switch direction 5. As an example, the second track switch direction 5 can be substantially transverse or perpendicular to the first transport direction 1 and/or the second transport direction 1′. In some implementations, the second substrate transport unit 150 is configured to laterally displace the at least a first substrate 10 in the second track switch direction 5.

According to some embodiments, which can be combined with other embodiments described herein, the apparatus 100′ is configured to move the at least a first substrate 10 or the carrier 20 having the at least a first substrate 10 positioned thereon from the first transportation path 130 to the second transportation path 132 and/or from the second transportation path 132 to the first transportation path 130 in the first area 112. In particular, the first substrate transport unit 140 in the first area 112 can be configured to move the at least a first substrate 10 or the carrier 20 having the at least a first substrate 10 positioned thereon from the second transportation path 132 to the first transportation path 130 and/or vice versa.

The apparatus 100′ can be configured to move the substrate from the first transportation path 130 to the second transportation path 132 and/or from the second transportation path 132 to the first transportation path 130 in the second area 116. In particular, the second substrate transport unit 150 in the second area 116 can be configured to move the at least a first substrate 10 or the carrier 20 having the at least a first substrate 10 positioned thereon from the first transportation path 130 to the second transportation path 132 and/or vice versa.

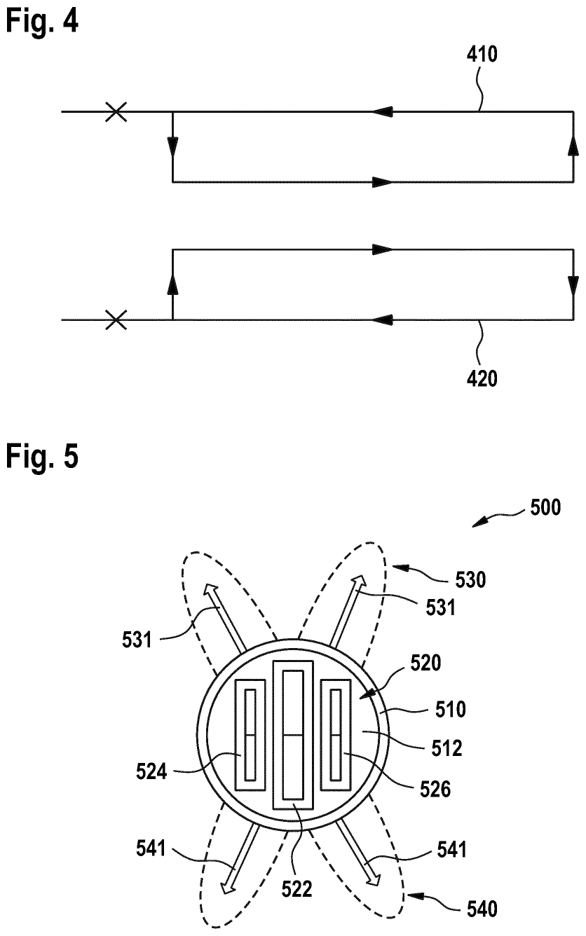

In some implementations, the vacuum chamber 110 is configured to provide a loop-shaped transportation path for the at least a first substrate 10 within the vacuum chamber 110. As an example, the loop-shaped transportation path can include the first transportation path 130 and the second transportation path 132. The first transportation path 130, the second transportation path 132, the first track switch direction 4 in the first area 112 and the second track switch direction 5 in the second area 116 can provide the loop-shaped transportation path, as it is exemplarily illustrated in FIG. 4. The loop-shaped transportation path can provide for a continuous or quasi-continuous movement of the substrates through the vacuum chamber 110, increasing an efficiency and/or throughput of the apparatus 100′. Further, a complexity of the apparatus 100′ for vacuum deposition can be reduced, for example, since only one vacuum lock, such as a vacuum lock 160, can be provided for inserting and removing substrates into and from the vacuum chamber 110, without reducing a throughput of the apparatus 100′.

Exemplarily, the at least a first substrate 10 can be inserted into the first area 112 of the vacuum chamber 110 through the vacuum lock 160, for example, onto the second transportation path 132. The at least a first substrate 10 or the carrier 20 having the at least a first substrate 10 positioned thereon can be laterally displaced in the first area 112 in the first track switch direction 4 from the second transportation path 132 towards and onto the first transportation path 130. The carrier 20 can be driven along the first transportation path 130 in the first transport direction 1 from the first area 112 into the first deposition area 114. The carrier 20 is moved past the one or more deposition sources 120 at or in the first deposition area 114 to deposit a material layer on the at least a first substrate 10. After the vacuum deposition process, the carrier 20 moves further along the first transportation path 130 into the second area 116. The carrier 20 having the coated substrate 11 positioned thereon is laterally displaced in the second area 116 in the second track switch direction 5 opposite the first track switch direction 4 from the first transportation path 130 to the second transportation path 132. The carrier 20 is driven along the second transportation path 132 in the third transport direction 2 opposite the first transport direction 1 from the second area 116 through the first deposition area 114 and into the first area 112. The coated substrate 11 or the carrier 20 having the coated substrate 11 positioned thereon can exit the vacuum chamber 110 through the load lock or vacuum lock 160.

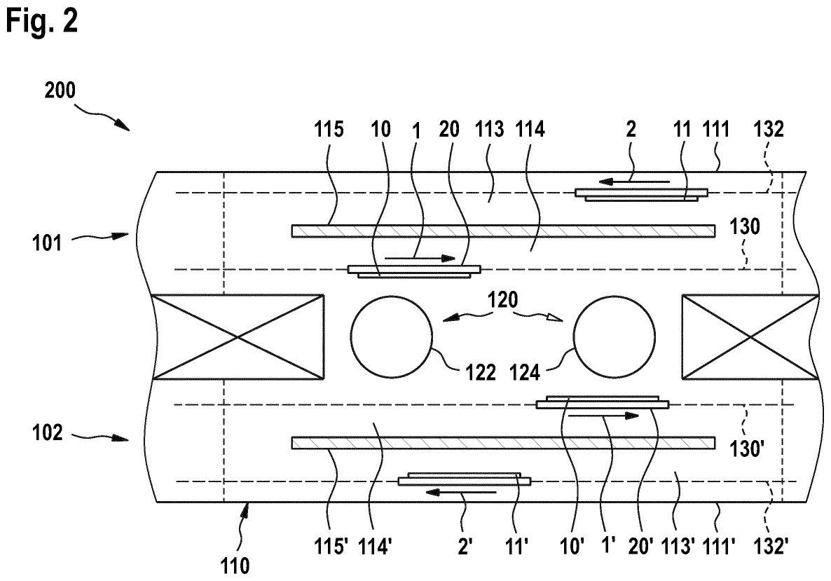

The first transportation path 130 can be closer to the one or more deposition sources 120 than the second transportation path 132. In particular, a partition (not shown) as described with respect to FIG. 2 can be provided between the first transportation path 130 and the second transportation path 132 in the first deposition area 114. The vacuum deposition process can be conducted for substrates positioned on the first transportation path 130, but may not be conducted for substrates positioned on the second transportation path 132. In some implementations, the first transportation path 130 can be referred to as “forward path” and/or the second transportation path 132 can be referred to as “return path”.

FIG. 2 shows a schematic top view of an apparatus 200 for vacuum deposition, such as sputter deposition, on a substrate according to embodiments described herein.

The apparatus 200 includes the vacuum chamber 110 having the first deposition area 114, a second deposition area 114′, and a chamber wall. As an example, the chamber wall is a vertical chamber wall of the vacuum chamber 110. In some implementations, the chamber wall can include a first chamber wall 111 adjacent to the first deposition area 114 and a second chamber wall 111′ adjacent to the second deposition area 114′. The first chamber wall 111 and the second chamber wall 111′ can define boundaries of the vacuum chamber 110, e.g., substantially parallel to a first transport direction 1 through the first deposition area 114 and/or a second transport direction l′ through the second deposition area 114′. The first chamber wall 111 and the second chamber wall 111′, which can be vertical chamber walls, can be substantially parallel to each other.

The apparatus 200 includes one or more deposition sources 120, such as one or more bi-directional sputter deposition sources, arranged between the first deposition area 114 and the second deposition area 114′. As an example, the first deposition area 114 can be provided at a first side of the one or more deposition sources 120 and the second deposition area 114′ can be provided at a second side of the one or more deposition sources 120 opposite the first side. The one or more deposition sources 120 are configured for vacuum deposition on at least a first substrate 10 transported in the first transport direction 1 through the first deposition area 114 past the one or more deposition sources 120 and for vacuum deposition on at least a second substrate 10′ transported in the second transport direction 1′ through the second deposition area 114′ past the one or more deposition sources 120. As an example, the one or more deposition sources 120 are configured for simultaneous vacuum deposition on the at least a first substrate 10 and the at least a second substrate 10′.

In some implementations, the first transport direction 1 and the second transport direction 1′ point in substantially the same direction, for example, parallel to each other. In other implementations, the first transport direction 1 and the second transport direction 1′ point in substantially opposite directions. The first transport direction 1 and the second transport direction 1′ can be substantially horizontal directions.

At least one deposition area of the first deposition area 114 and the second deposition area 114′ includes a chamber region between the one or more deposition sources 120 and the chamber wall of the vacuum chamber. The chamber region is separated into the respective deposition area, such as the first deposition area 114 or the second deposition area 114′, and a transportation area. The transportation area is arranged between the respective deposition region and the chamber wall. The apparatus 200 is configured for substrate transportation along the first transportation path through the respective deposition area and along the second transportation path through the transportation area. According to some embodiments, which can be combined with embodiments described herein, the transportation area is configured as at least one of a substrate cooling area and a substrate waiting area. Coated substrates 11 and 11′ can cool after deposition and/or wait for a load lock chamber to open and/or a path to become clear.

As an example, at least one deposition area of the first deposition area 114 and the second deposition area 114′ includes a partition provided in a chamber region between the one or more deposition sources 120 and the chamber wall. As an example, a first partition 115 is provided in a chamber region between the one or more deposition sources 120 and the first chamber wall 111. A second partition 115′ can be provided in a chamber region between the one or more deposition sources 120 and the second chamber wall 111′. According to some embodiments, the partition, such as the first partition 115 and the second partition 115′, can be separation walls, such as vertical walls. In some implementations, the partition can extend substantially parallel to the chamber wall and/or the respective transport direction, such as the first transport direction 1 and the third transport direction 2.

The chamber region can be separated into the respective deposition area and the transportation area, e.g., using the partition, wherein the transportation area is at least partially shielded from the one or more deposition sources 120. As an example, the first partition 115 separates the chamber region between the one or more deposition sources 120 and the first chamber wall 111 into the first deposition area 114 and a first transportation area 113. The second partition 115′ can separate the chamber region between the one or more deposition sources 120 and the second chamber wall 111′ into the second deposition area 114′ and a second transportation area 113′. In further examples, no partition is provided and the transportation area is at least partially shielded from the one or more deposition sources 120 using the substrates or carriers transported along the first transportation path, such as the first transportation paths 130 and 130′ extending through the first deposition area 114 and the second deposition area 114′, respectively.

The apparatus 200 is configured for substrate transportation along the first transportation path through the respective deposition area and along the second transportation path through the respective transportation area. As an example, the first transportation paths 130 and 130′ extend through the first deposition area 114 and the second deposition area 114′, respectively. Second transportation paths 132 and 132′ can extend through the first transportation area 113 and the second transportation area 113′, respectively. The first transportation path(s) and the second transportation path(s) can extend substantially parallel to each other. In some implementations, the transport directions on the first transportation path(s), such as the first transport direction 1 and the second transport direction 1′, point in substantially the same direction. The transport directions on the second transportation path(s), such as a third transport direction 2 and a fourth transport direction 2′, can point in substantially the same direction. According to some embodiments, the transport direction on the first transportation path and the transport direction on the second transportation path point in opposite directions. In particular, the first transportation paths, such as the first transportation paths 130 and 130′, are forward transportation paths. The second transportation path(s), such as the second transportation paths 132 and 132′, can be return transportation paths. In other implementations, the first transportation paths, such as the first transportation paths 130 and 130′, are return transportation paths. The second transportation path(s), such as the second transportation paths 132 and 132′, can be forward transportation paths. The circulation direction in each loop can be clockwise or counter-clockwise.

The transportation area is shielded from the one or more deposition sources 120 using the partition or substrates on the first transportation path and can provide a shielded return path for coated substrates 11 and 11′. In particular, the coated substrates 11 and 11′ can be returned to an original position and can, for example, exit the vacuum chamber 110 through the same load lock through which the uncoated substrate has entered the vacuum chamber 110. A continuous or quasi-continuous substrate transportation through the vacuum chamber 110 can be provided. An increased number of substrates can be handled simultaneously within the vacuum chamber 110. An efficiency and throughput of the apparatus 200 for vacuum deposition can be increased.

According to some embodiments, which can be combined with other embodiments described herein, the apparatus 200 is configured for simultaneous vacuum deposition on the at least a first substrate 10 and at least a second substrate 10′. In some implementations, the at least a first substrate 10 is transported through the first deposition area 114 but not through the second deposition area 114′. Likewise, the at least a second substrate 10′ is transported through the second deposition area 114′ but not through the first deposition area 114. In other words, the apparatus 200 can have two in-line units, such as a first (upper) in-line unit 101 and a second (lower) in-line unit 102, sharing common deposition sources, wherein the two in-line units are not connected via substrate transportation paths. In particular, a substrate is not moved between the two in-line units. The at least a first substrate 10 can be only processed in the first (upper) in-line unit 101 of the apparatus 200 and the at least a second substrate 10′ can be only processed in the second (lower) in-line unit 102 of the apparatus 200.

According to some embodiments, which can be combined with other embodiments described herein, the one or more deposition sources are bi-directional deposition sources such as bi-directional sputter deposition sources. According to some embodiments, the one or more bi-directional sputter deposition sources can be configured to provide a first plasma racetrack and a second plasma racetrack opposing the first plasma racetrack. The bi-directional sputter deposition sources are further described with respect to FIG. 5.

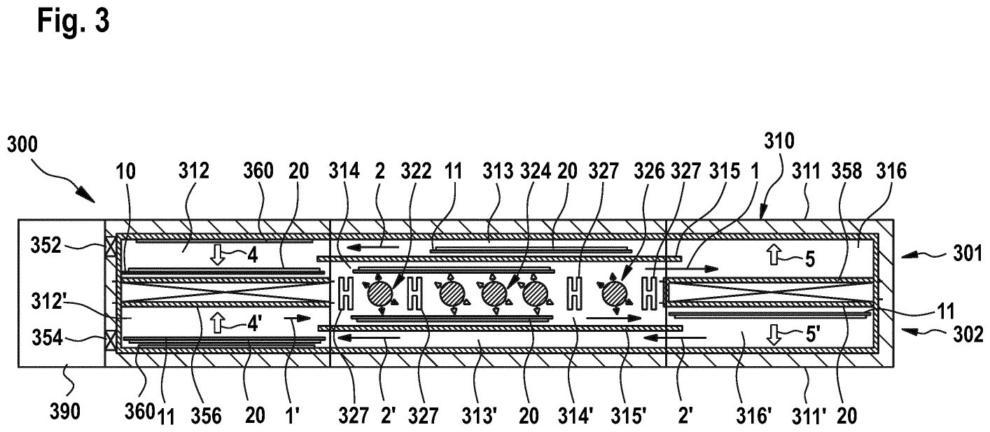

FIG. 3 shows a schematic top view of an apparatus 300 for vacuum deposition on a substrate according to yet further embodiments described herein. The apparatus 300 can be similar to the apparatuses of FIGS. 1A, B and 2 and thus, the description given with respect to FIGS. 1A, B and 2 also applies to the apparatus 300 of FIG. 3. Likewise, the features of the apparatus 300 of FIG. 3 described in the following can be implemented in the apparatuses of FIGS. 1A, B and 2.

According to some embodiments, which can be combined with other embodiments described herein, the vacuum chamber 310 includes the first deposition area 314, the second deposition area 314′, the first area 312, and another first area 312′. The one or more deposition sources are provided at the second deposition area 314′. The one or more deposition sources are configured for vacuum deposition on at least a second substrate 10′ while the at least a second substrate 10′ is transported through the second deposition area 314′ along the second transport direction 1′ past the one or more deposition sources. In some implementations, the one or more deposition sources are bi-directional deposition sources arranged between the first deposition area 314 and the second deposition area 314′, wherein the bi-directional deposition sources are configured for simultaneous vacuum deposition on the at least a first substrate 10 and the at least a second substrate 10′.

In some implementations, the vacuum chamber 310 includes another second area 316′, wherein the second deposition area 314′ is arranged between the other first area 312′ and the other second area 316′. The other second area 316′ can be configured similarly or identically to the second area 316.

The apparatus 300 can include a third substrate transport unit in the other first area 312′, wherein the third substrate transport unit is configured for moving the at least a second substrate 10′ within the other first area 312′ in a third track switch direction 4′, which is different from the second transport direction 1′. In some implementations, the apparatus 300 includes a fourth substrate transport unit in the other second area 316′, which is configured for moving the at least a second substrate 10′ within the other second area 316′ in a fourth track switch direction 5′, which is different from the second transport direction 1′. At least one of the third substrate transport unit and the fourth substrate transport unit can be configured similarly or identically to the first and second substrate transport units.

The first area 312, the first deposition area 314 and the second area 316 can provide a first in-line unit 301 of the apparatus 300 and the other first area 312′, the second deposition area 314′ and the other second area 316′ can provide a second in-line unit 302 of the apparatus 200. The first in-line unit 301 and the second in-line unit 302 can extend parallel to each other. In particular, the apparatus 300 can include two in-line units, which are combined in a mirrored manner.

According to some embodiments, which can be combined with other embodiments described herein, the apparatus 300 can be configured as a dual-line apparatus, for example, provided with one single vacuum chamber. As an example, the apparatus 300 has two first areas and two second areas. One first area 312 of the two first areas can be provided adjacent to the first deposition area 314 and the other first area 312′ of the two first areas can be provided adjacent to the second deposition area 314′. One second area 316 of the two second areas can be provided adjacent to the first deposition area 314 and the other second area 316′ of the two second areas can be provided adjacent to the second deposition area 314′. As an example, the first deposition area 314 can be sandwiched between the one first area 312 and the one second area 316. Likewise, the second deposition area 314′ can be sandwiched between the other first area 312′ and the other second area 316′.

In some implementations, at least one deposition area of the first deposition area 314 and the second deposition area 314′ includes a partition provided in a chamber region between the one or more deposition sources and the chamber wall. As an example, a first partition 315 is provided in a chamber region between the one or more deposition sources and the first chamber wall 311. A second partition 315′ can be provided in a chamber region between the one or more deposition sources and the second chamber wall 311′. The partition separates the chamber region into the respective deposition area and a transportation area, wherein the transportation area is at least partially shielded from the one or more deposition sources. As an example, the first partition 315 separates the chamber region between the one or more deposition sources and the first chamber wall 311 into the first deposition area 314 and a first transportation area 313. The second partition 315′ can separate the chamber region between the one or more deposition sources and the second chamber wall 311′ into the second deposition area 314′ and a second transportation area 313′.

The apparatus 300 can include the one or more bi-directional sputter deposition sources, such as one or more first sputter deposition sources 322, one or more second sputter deposition sources 324 and one or more third sputter deposition sources 326. According to some embodiments, which can be combined with embodiments described herein, the deposition area, such as the first deposition area 314 and/or the second deposition area 314′, can be a scalable chamber section. As an example, the vacuum chamber 310 can be manufactured or constructed from at least three sections. The at least three sections can be connected to each other to form the vacuum chamber 310. The first section of the at least three sections provides the first area(s). The second section of the at least three sections provides the scalable chamber section and the deposition area(s), and the third section of the at least three sections provides the second area(s).

The scalable chamber section provides the processing tools, for example, the one or more deposition sources. The scalable chamber section can be provided in various sizes in order to allow for a varying amount of processing tools to be provided in the scalable chamber section. As an example, the apparatus 300 is configured to accommodate variable numbers of deposition sources, for example, between the first deposition area 314 and the second deposition area 314′.

The deposition area, such as the first deposition area 314 and/or the second deposition area 314′, can have two or more deposition sub-areas each having one or more deposition sources. Each deposition sub-area can be configured for layer deposition of a respective material. The deposition sources in at least some of the deposition sub-areas can be different. In some implementations, at least some of the two or more deposition sub-areas can be configured for deposition of different materials on the at least a first substrate 10 and the at least a second substrate 10′. FIG. 3 shows a scalable chamber section with five deposition sources. The first deposition source (previously referred to as “one or more first sputter deposition sources 322”) can provide a first material. The second, the third, and the fourth deposition source (previously referred to as “one or more second sputter deposition sources 324”) can provide a second material. The fifth deposition source (previously referred to as “one or more third sputter deposition sources 326”) can provide a third material. For example, the third material can be the same material as the first material. Accordingly, a three layer stack can be provided on the substrate, such as a large area substrate. For example, the first and the third material can be molybdenum and the second material can be aluminum.

According to some embodiments, which can be combined with other embodiments described herein, the number of deposition sources such as sputter deposition sources or cathodes per material and/or the power provided to the individual deposition sources or cathodes can be varied to tune the desired thickness relation between the respective layers. As an example, a number of the deposition sources is selected according to a thickness of a material layer that is to be deposited on a substrate passing the deposition sources. Accordingly, the number of cathodes and the power to the individual cathodes can be used as tuneable variables to achieve a desired thickness of each layer at the same passing speed of the substrate moving past the cathodes. As an example, when different material layers are to be deposited on the substrate (for example, sputter deposition sources could include the above-mentioned aluminum cathodes and molybdenum cathodes to sputter at least two different material layers), a thickness of the deposited layers can be controlled by adjusting or scaling a number of cathodes in the deposition area or respective deposition sub-area.

The two or more deposition sub-areas can be separated from each other using sputter separation units 327 (also referred to as “sputter separation shielding”). As an example, between the deposition sources for providing different materials on the substrate, sputter separation units 327 can be provided. The sputter separation units 327 can provide for separating a first processing area in the deposition area, such as the first deposition area 314, from a second processing area in the deposition area, wherein the first processing area can have a different environment, for example, different processing gases and/or a different pressure, as compared to the second processing area. The sputter separation units 327 have an opening configured for allowing a passage of substrates through the opening.

According to some embodiments, which can be combined with other embodiments described herein, the vacuum chamber 310 of the apparatus 300 provides for a simultaneous processing of two or more substrates using two in-line units in order to increase the throughput.

FIG. 3 shows the first (upper) in-line unit 301, in which substrates (the at least a first substrate 10) can be processed and the second (lower) in-line unit 302, in which substrates (the at least a second substrate 10′) can be processed. The first in-line unit 301 and the second in-line unit 302 share common deposition sources. The common deposition sources for a simultaneous deposition of material onto substrates allow for a higher throughput. The simultaneous processing using two in-line units within one vacuum chamber 310 of the apparatus 300 reduces a footprint of the apparatus 300. Particularly for large area substrates, the footprint can be a relevant factor for reducing the cost of ownership for the apparatus 300.

The substrates, as for example shown in FIG. 3, have a continuous or quasi-continuous flow along the deposition sources. The substrates can be provided on carriers 20 within the vacuum chamber 310. The substrates enter the apparatus 300 through load locks, which can include a first gate valve 352 configured for access to the first (upper) in-line unit 301 and a second gate valve 354 configured for access to the second (lower) in-line unit 302. Load lock chambers, which can be vented and evacuated, can be provided at the gate valves such that the vacuum in the apparatus 300 can be maintained even during the loading and unloading of the substrates. As an example, a system configured for vacuum deposition on a substrate may include the apparatus according to the embodiments described herein, and a load lock chamber 390 connected to the apparatus, wherein the load lock chamber 390 is configured to load substrates onto the first transportation path or the second transportation path and to receive substrates from the first transportation path or the second transportation path.

The first area(s) and the second area(s) can be track switch areas (first area(s): track switching load/unload; second area(s): track switching return). The first area(s) and the second area(s) are sufficiently long to allow for the track switch. The track switch areas can be at each end of the dynamic-deposition zone. This allows for a continuous substrate flow (dynamic deposition) without the need for “run up” and “run away” chamber sections. The in-line processing apparatus has a smaller footprint.

As illustrated by the arrows indicating the first transport direction 1 in the first in-line unit 301 and the second transport direction 1′ in the second in-line unit 302, a carrier 20 with a substrate provided thereon moves along the respective transport direction past the one or more deposition sources. In the one first area 312, the first in-line unit 301 may include a first track switching and/or load-unload area, and the second in-line unit 302 may include a second track switching and/or load-unload area in the other first area 312′. The first track switching and/or load-unload area and the second track switching and/or load-unload area can be separated from each other by a first separation 356. The two track switching and/or load-unload areas can be utilized simultaneously in order to improve the throughput of the apparatus 300.

Within the track switching and/or load-unload area, the carrier 20 with the substrate is moved on a transportation path, such as the first transportation path for processing of the substrate. Thereafter, one substrate after the other is moved past the processing tools, for example, the one or more deposition sources. Accordingly, the substrates are processed in the deposition area(s) of the vacuum chamber 310, for example, the scalable chamber section.

The second area(s) can be track switching return areas, such as a first track switching return area of the first in-line unit 301 and a second track switching return area of the second in-line unit 302. The first track switching return area and the second track switching return area can be separated by a second separation 358. The track switching return areas can provide for a movement substantially transverse to the transport direction past the one or more deposition sources (the first transport direction 1 and/or the second transport direction 1′) in the respective track switch direction. A carrier 20 with the coated substrate 11 can return to the respective first area and optionally to the load lock chamber (not shown) at a distance with respect to the one or more deposition sources different (i.e., larger) from the distance during processing.

In some implementations, the apparatus 300 further includes one or more substrate heating devices 360 in at least one of the first area, the second area, and the transportation area. The one or more substrate heating devices 360 are configured for heating the substrate to a predetermined temperature. As an example, the first area can have one or more processing devices, such as the one or more substrate heating devices 360, configured for heating or pre-heating the substrate.

According to some embodiments, the speed of the substrate during transportation thereof through the deposition area, such as the first deposition area 314 and the second deposition area 314′, is substantially constant. A uniformity of the deposited layers can be ensured due to the constant speed. A thickness of the deposited layers can be controlled by the number of cathodes and/or by adjusting the power to the individual cathodes. Specifically, a number of aluminum cathodes and power to individual moly cathodes can be the variables to tune to achieve desired thickness of each layer at the same passing speed.

FIG. 4 shows schematic views of transportation paths in the apparatus for vacuum deposition forming loops within the vacuum chamber according to embodiments described herein. FIG. 4 shows two loop-shaped transportation paths of the apparatus of FIG. 3, namely a first (upper) loop-shaped transportation path 410 of the first in-line unit and a second (lower) loop-shaped transportation path 420 of the second in-line unit. The circulation direction in each loop can be clockwise or counter-clockwise. In particular, the circulation directions may also be opposite to what is shown in FIG. 4.

As an example, the substrate or carrier can switch paths within the first area and/or the second area such that the transport loop is provided. As shown in FIG. 4, the substrate can be moved within the first area transverse to the transport direction from the second transportation path onto the first transportation path. The substrate can be transported along the first transportation path through the deposition area for layer deposition thereon and can then be moved into the second area where the substrate is moved back to the second transportation path using a movement transverse to the transport direction. The transverse movements in the first area and the second area can be movements in opposite directions. The substrate can then be moved through the second area and the deposition area back towards the lock or gate valve in the first area, wherein the coated substrate can be discharged to the outside.

FIG. 5 shows a schematic top view of a sputter deposition source 500 according to embodiments described herein. The sputter deposition source 500 can be referred to as “bi-directional sputter deposition source”. The bi-directional sputter deposition source can be implemented in the apparatuses for vacuum deposition according to the embodiments described herein.

The sputter deposition source 500 includes a cylindrical sputter cathode 510 rotatable around a rotational axis, and a magnet assembly 520 configured to provide a first plasma racetrack 530 and a second plasma racetrack 540 on opposite sides of the cylindrical sputter cathode 510. The magnet assembly 520 includes two, three or four magnets, such as a first magnet 522 and a pair of second magnets. The first magnet 522 and/or a pair of second magnets can each include a plurality of sub-magnets. As an example, each magnet can consist of a set of sub-magnets.

The two or three or four magnets, such as the first magnet 522 and the pair of second magnets, are configured for generating both the first plasma racetrack 530 and the second plasma racetrack 540. In other words, each magnet of the first magnet 522 and the pair of second magnets participates in the generation of both plasma racetracks. In some implementations, the magnet assembly 520 is configured to provide the first plasma racetrack 530 and the second plasma racetrack 540 substantially symmetrical with respect to the rotational axis.

The first magnet 522 and the pair of second magnets each generate substantially identical magnetic fields on both sides of the cylindrical sputter cathode 510. A sputter performance on both sides of the cylindrical sputter cathode 510 can be made essentially the same. In particular, a sputter rate on both sides can be substantially identical, such that characteristics, e.g., a layer thickness, on two simultaneously coated substrates can be substantially the same.

The rotational axis can be a cylinder axis of the cylindrical sputter cathode 510. The first magnet 522 and the pair of second magnets can be symmetrical with respect to the rotational axis of the cylindrical sputter cathode 510. In some implementations, the rotational axis of the cylindrical sputter cathode 510 is a substantially vertical rotational axis. “Substantially vertical” is understood particularly when referring to the orientation of the rotational axis, to allow for a deviation from the vertical direction or orientation of ±20° or below, e.g. of ±10° or below. Yet, the axis orientation is considered substantially vertical, which is considered different from the horizontal orientation.

The cylindrical sputter cathode 510 includes a cylindrical target and optionally a backing tube. The cylindrical target can be provided on the backing tube, which can be a cylindrical, metallic tube. The cylindrical target provides the material to be deposited on the substrates. Within the cylindrical sputter cathode 510, a space 512 for a cooling medium, for example, water, can be provided.

The cylindrical sputter cathode 510 is rotatable around a rotational axis. The rotational axis can be a cylinder axis of the cylindrical sputter cathode 510. The term “cylinder” can be understood as having a circular bottom shape and a circular upper shape and a curved surface area or shell connecting the upper circle and the small lower circle. A single magnet set including the first magnet 522 and the pair of second magnets is configured for producing the magnetic fields on both (e.g., opposite) sides of the rotary target, for example, both sides of the curved surface area or shell to generate the plasma racetracks.

The cylindrical sputter cathode 510 having the magnet assembly 520 can provide for magnetron sputtering for deposition of layers. As used herein, “magnetron sputtering” refers to sputtering performed using a magnetron, i.e. the magnet assembly 520, that is, a unit capable of generating a magnetic field. The magnet assembly 520 is arranged such that the free electrons are trapped within the generated magnetic field. The magnetic field provides the plasma racetracks on the target surface. The term “plasma racetrack” as used throughout the present disclosure can be understood in the sense of electron traps or magnetic-field electron traps provided at or near the target surface. In particular, magnetic field lines penetrating the cylindrical sputter cathode 510 lead to a confinement of electrons in front of the target surface so that due to the high concentration of electrons, a large number of ions and therefore a plasma is produced. The plasma racetracks can also be referred to as “plasma zones”.

The plasma racetracks of the present disclosure are distinguished from racetrack grooves, which can occur when using planar magnetrons. The presence of a racetrack groove limits a target consumption. When using a rotating cylindrical target, no racetrack groove corresponding to the magnet configuration is formed in the rotating target surface. As a result, a high target material utilization can be achieved.

During sputtering, the cylindrical sputter cathode 510 and the target are rotated around the magnet assembly 520 including the first magnet 522 and the pair of second magnets, such as a first magnet unit 524 and a second magnet unit 526. Specifically, the first magnet unit 524 and the second magnet unit 526 form the pair of second magnets. The first plasma racetrack 530 and the second plasma racetrack 540 can be essentially stationary with respect to the magnet assembly 520. The first plasma racetrack 530 and the second plasma racetrack 540 sweep over the surface of the target while the cylindrical sputter cathode 510 and the target rotate over the magnet assembly 520. The cylindrical sputter cathode 510 and the target rotate below the plasma racetracks.

According to some embodiments, which can be combined with other embodiments described herein, the sputter deposition source 500 provides for the first plasma racetrack 530 and the second plasma racetrack 540, wherein the second plasma racetrack 540 is essentially on the opposite side of the cylindrical sputter cathode 510, i.e., on an opposite side of the cylindrical sputter cathode 510. In particular, the first plasma racetrack 530 and the second plasma racetrack 540 are symmetrically provided on two opposing sides of the cylindrical sputter cathode 510.

A plasma racetrack, such as each of the first plasma racetrack 530 and the second plasma racetrack 540, can form one single plasma zone. Even though FIG. 5 shows two portions of each of the first plasma racetrack 530 and the second plasma racetracks 540, the two portions of the respective racetrack are connected with curved portions at the end of the racetrack to form a single plasma zone or a single plasma racetrack. Accordingly, FIG. 5 shows two plasma racetracks.

The plasma racetracks are formed by one magnet assembly 520 having the first magnet 522 and a pair of second magnets. Accordingly, the first magnet 522 is involved in the generation of the first plasma racetrack 530 and the second plasma racetrack 540. Similarly, the pair of second magnets is also involved in the generation of the first plasma racetrack 530 and the second plasma racetrack 540. The first magnet 522 and the magnet units of the pair of second magnets can be next to each other, such that the first magnet 522 is between the pair of second magnets.

According to some embodiments, which can be combined with other embodiments described herein, the first magnet 522 has a first magnetic pole in the direction of the first plasma racetrack 530 and a second magnetic pole in the direction of the second plasma racetrack 540. The first magnetic pole can be a magnetic south pole and the second magnetic pole can be a magnetic north pole. In other embodiments, the first magnetic pole can be a magnetic north pole and the second magnetic pole can be a magnetic south pole. The pair of second magnets can have the second magnetic poles (e.g., south poles or north poles) in the direction of the first plasma racetrack 530 and the first magnetic poles (e.g., north poles or south poles) in the direction of the second plasma racetrack 540.

Accordingly, three magnets form two magnetrons, one magnetron for generating the first plasma racetrack 530 and one magnetron for generating the second plasma racetrack 540. Sharing magnets for the two plasma racetracks reduces potentially occurring differences in the first plasma racetrack 530 and the second plasma racetrack 540. The arrows 531 show the main direction of material emission from the target upon bombardment of the ions of the plasma in the first plasma racetrack 530. The arrows 541 show the main direction of material emission from the target upon bombardment of the ions of the plasma in the second plasma racetrack 540.

According to some embodiments, which can be combined with other embodiments described herein, the magnet assembly 520 is stationary in the cylindrical sputter cathode 510. The stationary magnet assembly defines stationary plasma racetracks, such as the first plasma racetrack 530 and the second plasma racetrack 540. The stationary plasma racetracks can face respective substrates. The term “stationary plasma racetrack” is to be understood in the sense that the plasma racetrack does not rotate together with the cylindrical sputter cathode 510 around the rotational axis.

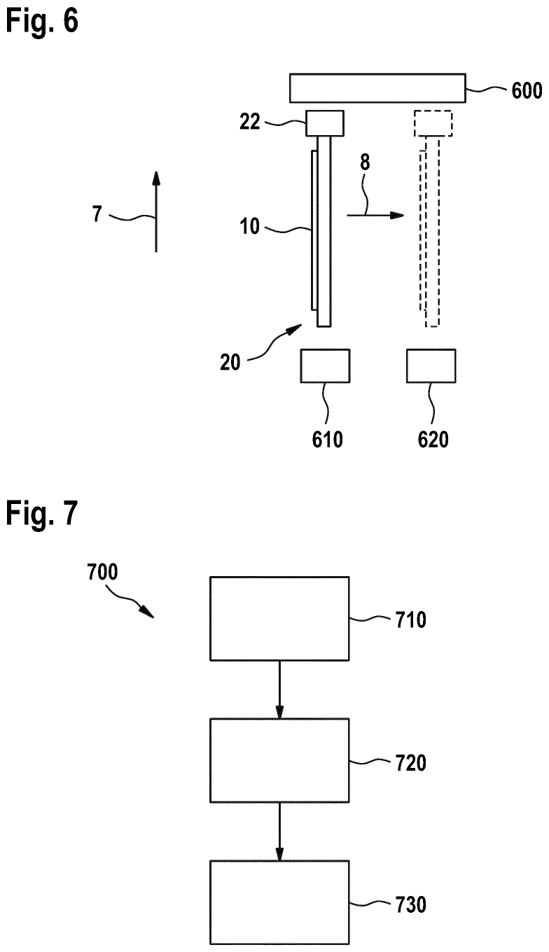

FIG. 6 shows a schematic view of a substrate transport unit for moving the substrate or carrier 20 having the substrate positioned thereon in the track switch direction according to embodiments described herein. The substrate, such as the at least a first substrate 10, is oriented vertically, as indicated by arrow 7.

According to some embodiments, the apparatus for vacuum deposition includes a transportation system. The transportation system can include one or more substrate transport units 600, for example, the first substrate transport unit in the first area and the second substrate transport unit in the second area. The substrate transport unit 600 is configured for moving or transporting the substrate or the carrier 20 having the substrate positioned thereon in the track switch direction different from the transport direction, e.g., perpendicular to the transport direction (indicated by arrow 8).

As an example, one or more track-switch MagLev actuators and associated linear motors, located e.g. outside the vacuum chamber(s), can be provided for performing the track switch between the first transportation path 610 and the second transportation path 620. Accordingly, a motion of the carriers inside the vacuum with no mechanical contact can be provided. A particle performance can be improved. However, the present disclosure is not limited to a contactless lateral displacement. In some implementations, mechanical devices such as rollers can be used to laterally move the carrier 20, e.g., between the first transportation path 610 and the second transportation path 620 and/or vice versa.

In some implementations, the transportation system includes a magnetic levitation system for holding the carrier in a suspended state. Optionally, the transportation system can use a magnetic drive system configured for moving or conveying the carrier 20 in the transport direction past the one or more deposition sources.

The carrier 20 can be supported within the apparatus with the magnetic levitation system. The magnetic levitation system includes magnets which support the carrier 20 in a hanging (vertical) position without mechanical contact. In particular, the carrier 20 can have magnetic units 22 configured to interact with the magnet of the magnetic levitation system. The magnetic levitation system provides a levitation, i.e. contactless support, of the carrier 20. Accordingly, particle generation due to movement of the carrier within the vacuum chamber can be reduced or avoided. The magnetic levitation system includes magnets, which provide a force to the top of the carrier 20, for example, the magnetic units 22, which is substantially equal to the gravity force. That is, the carrier 20 is suspended without contact below the magnets of the magnetic levitation system.

FIG. 7 shows a flow chart of a method 700 for vacuum deposition on a substrate according to embodiments described herein. The method 700 can utilize the apparatuses, such as the apparatus for vacuum deposition having the bi-directional deposition sources, according to the embodiments described herein.

The method 700 includes in block 710 a moving of at least a first substrate in a first transport direction along a first transportation path through a first deposition area of a vacuum chamber past one or more deposition sources, such as one or more sputter deposition sources, to deposit a material layer on the at least a first substrate, and in block 720 a moving of the at least a first substrate in a first track switch direction different from the first transport direction at least one of before and after the material layer has been deposited on the at least a first substrate. In some implementations, the method further includes in block 730 a moving of at least a second substrate in a second transport direction along another first transportation path through a second deposition area of the vacuum chamber past the one or more deposition sources to deposit another material layer on the at least a second substrate, wherein the one or more deposition sources are provided between the first deposition area and the second deposition area.

According to some embodiments, which can be combined with embodiments described herein, the first transportation path is a forward transportation path, and the second transportation path is a return transportation path.

According to embodiments described herein, the method for vacuum deposition on a substrate can be conducted using computer programs, software, computer software products and the interrelated controllers, which can have a CPU, a memory, a user interface, and input and output devices being in communication with the corresponding components of the systems and apparatuses according to the embodiments described herein.

The present disclosure provides at least some of the following advantages. The embodiments described herein provide multiple transport possibilities for substrates within a vacuum chamber in a plurality of different directions. In particular, multiple transportation paths extending through a plurality of distinct areas within a vacuum chamber are provided such that a plurality of substrates can simultaneously be processed.

As an example, the vacuum chamber can have at least two distinct areas, such as a deposition area and at least one of a first area, a second area, and a transportation area. The areas are distinct from each other and do not overlap. The first area and optionally the second area can provide an additional degree of freedom for the substrate movement. The additional degree of freedom, which is a movement of the substrate in a track switch direction, e.g., substantially transverse to the transport direction past the deposition sources, allows for an increased number of substrates that can be simultaneously put and/or processed in the vacuum chamber. In particular, an increased number of substrates can be handled simultaneously within the vacuum chamber. An efficiency and throughput of the apparatus for vacuum deposition can be increased. The transportation area, which can be shielded from the deposition sources using, for example, substrates transported through the deposition area or a partition, can extend substantially parallel to the deposition area and can provide a return path for coated substrates. In particular, coated substrates can be returned to an original position and can, for example, exit the vacuum chamber through the same load lock through which the uncoated substrate has entered the vacuum chamber.

While the foregoing is directed to embodiments of the disclosure, other and further embodiments of the disclosure may be devised without departing from the basic scope thereof, and the scope thereof is determined by the claims that follow.

1. An apparatus for vacuum deposition on a substrate, comprising:
a vacuum chamber having a first area and a first deposition area;
one or more deposition sources at the first deposition area, wherein the one or more deposition sources are configured for vacuum deposition on at least a first substrate while the at least a first substrate is transported along a first transport direction past the one or more deposition sources; and
a first substrate transport unit in the first area, wherein the first substrate transport unit is configured for moving the at least a first substrate within the first area in a first track switch direction, wherein the first track switch direction is different from the first transport direction.

2. The apparatus of claim 1, wherein the vacuum chamber includes a second area, wherein the first deposition area is arranged between the first area and the second area, and wherein the apparatus further includes a second substrate transport unit in the second area, wherein the second substrate transport unit is configured for moving the at least a first substrate within the second area in a second track switch direction, wherein the second track switch direction is different from the first transport direction.

3. The apparatus of claim 1, wherein the first substrate transport unit is configured to laterally displace the at least a first substrate in the first track switch direction.

4. The apparatus of claim 2, wherein at least one of the first track switch direction and the second track switch direction is perpendicular to the first transport direction.

5. The apparatus of claim 1, wherein the vacuum chamber includes a second deposition area and another first area, wherein the one or more deposition sources are further provided at the second deposition area, and wherein the one or more deposition sources are configured for vacuum deposition on at least a second substrate while the at least a second substrate is transported through the second deposition area along a second transport direction past the one or more deposition sources.

6. The apparatus of claim 5, further including a third substrate transport unit in the other first area, wherein the third substrate transport unit is configured for moving the at least a second substrate within the other first area in a third track switch direction, wherein the third track switch direction is different from the second transport direction.

7. The apparatus of claim 5, wherein the one or more deposition sources are bidirectional deposition sources arranged between the first deposition area and the second deposition area, wherein the bi-directional deposition sources are configured for simultaneous vacuum deposition on the at least a first substrate and the at least a second substrate.

8. The apparatus of claim 7, wherein the vacuum chamber includes another second area, wherein the second deposition area is arranged between the other first area and the other second area, and wherein the apparatus further includes a fourth substrate transport unit in the other second area, which is configured for moving the at least a second substrate within the other second area in a fourth track switch direction, wherein the fourth track switch direction is different from the second transport direction.

9. The apparatus of claim 8, wherein the first area, the first deposition area and the second area provide a first in-line unit of the apparatus and the other first area, the second deposition area and the other second area provide a second in-line unit of the apparatus, and wherein the first in-line unit and the second in-line unit extend parallel to each other.

10. The apparatus of claim 6, wherein at least one deposition area of the first deposition area and the second deposition area includes a chamber region between the one or more deposition sources and a chamber wall of the vacuum chamber, wherein the chamber region is separated into the respective deposition area and a transportation area, wherein the transportation area is arranged between the respective deposition region and the chamber wall, and wherein the apparatus is configured for substrate transportation along a first transportation path through the respective deposition area and along a second transportation path through the transportation area.

11. The apparatus of claim 10, further including a partition configured to separate the chamber region into the transportation area and the respective deposition area, wherein the partition is configured to at least partially shield the transportation area from the one or more deposition sources.

12. The apparatus of claim 10, wherein the transportation area is at least one of a substrate cooling area and a substrate waiting area.

13. The apparatus of claim 2, further including one or more substrate heating devices in at least one of the first area and the second area.

14. The apparatus of claim 1, wherein the apparatus is configured to accommodate variable numbers of the one or more deposition sources.

15. The apparatus of claim 1, wherein a number of the one or more deposition sources is selected according to a thickness of a material layer that is to be deposited on the substrates passing the one or more deposition sources.

16. The apparatus of claim 1, wherein the one or more deposition sources are selected from the group consisting of sputter deposition sources, thermal evaporation sources, plasma-enhanced chemical vapor deposition sources, and any combination thereof.

17. A system configured for vacuum deposition on a substrate, including:
the apparatus according to claim 1; and
a load lock chamber connected to the apparatus, wherein the load lock chamber is configured to load the substrates into the first area and to receive the substrates from the first area.

18. A method for vacuum deposition on a substrate, comprising:
moving at least a first substrate in a first transport direction along a first transportation path through a first deposition area of a vacuum chamber past one or more deposition sources to deposit a material layer on the at least a first substrate; and
moving the at least a first substrate in a first track switch direction different from the first transport direction at least one of before and after the material layer has been deposited on the at least a first substrate.

19. The method of claim 18, further including:
moving at least a second substrate in a second transport direction along another first transportation path through a second deposition area of the vacuum chamber past the one or more deposition sources to deposit another material layer on the at least a second substrate, wherein the one or more deposition sources are provided between the first deposition area and the second deposition area.

20. The apparatus of claim 2, wherein the second substrate transport unit is configured to laterally displace the at least a first substrate in the second track switch direction.
